(19) United States
(12) Patent Application Publication
(10) Pub. No.: US 2013/0015308 A1
(43) Pub. Date: Jan. 17, 2013

(54) HARD DISK DRIVE BRACKET

(71) Applicant: YU-CHEN TING, Tu-Cheng (TW)

(72) Inventor: YU-CHEN TING, Tu-Cheng (TW)

(73) Assignee: HON HAI PRECISION INDUSTRY CO., LTD., Tu-Cheng (TW)

(21) Appl. No.: 13/404,086

(22) Filed: Feb. 24, 2012

(30) Foreign Application Priority Data
Jul. 11, 2011 (TW) 100124506

(51) Int. Cl. H05K 7/14

(52) U.S. Cl. 248/309.1

(57) ABSTRACT

A bracket includes a bracket main body and a reinforce rib attached to the bracket main body. The bracket main body includes a base panel, a pair of side panels extending from opposite sides of the base panel, and a top panel connected between the pair of side panels. The top panel includes a first plate extending substantially perpendicularly from an upper edge of a first side panel of the pair of side panels and a second plate extending substantially perpendicularly from an upper edge of a second side panel of the pair of side panels. The first plate and the second plate partially overlap with each other and fix to each other. A first end of the reinforce rib is secured to the first plate. A second end of the reinforce rib is secured to the second plate.

### BACKGROUND

1. Technical Field

The present disclosure relates to brackets, and particularly to a bracket for hard disk drives.

2. Description of Related Art

With the advances in computer technology, people rely more on computers both in personal life and in business. Thus, a great deal of data storage space for storing information is needed. The information may be loaded in hard disk drives. Generally, the hard disk drives are accommodated in a bracket that is mounted in a computer. The bracket includes a base plate, a pair of side plates extending perpendicularly from opposite sides of the base plate, a pair of top flanges extending perpendicularly from top edges of the pair of side plates, and a top plate secured to the pair of top flanges by screws. The hard disk drives vibrate during operation, which also vibrates the bracket. As a result, the top plate may be easily deformed due to the vibration.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of an embodiment of a bracket for hard disk drives, the bracket including a bracket main body and a reinforce rib.

FIG. 2 is a schematic cross-sectional view of the bracket main body of FIG. 1.

FIG. 3 is the bracket main body of FIG. 1 viewed from another aspect.

FIG. 4 is an assembled view of the bracket of FIG. 1.

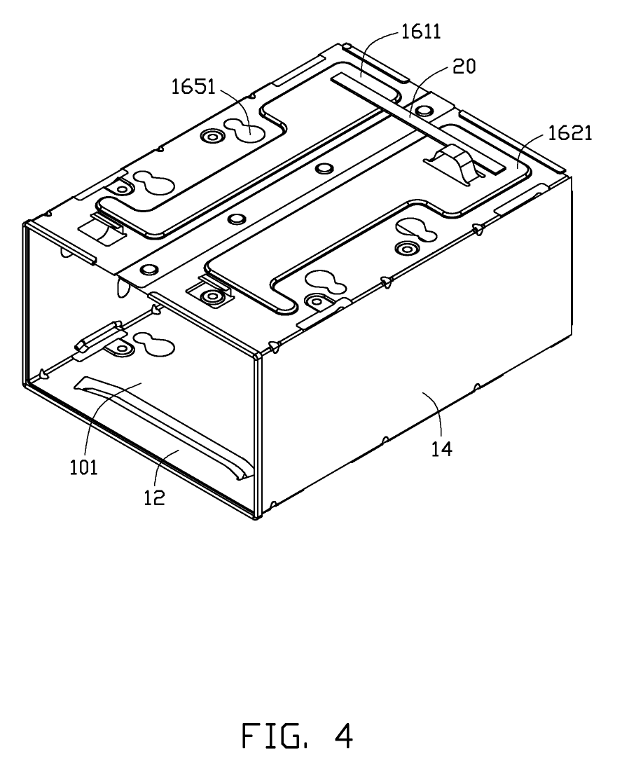

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean at least one.

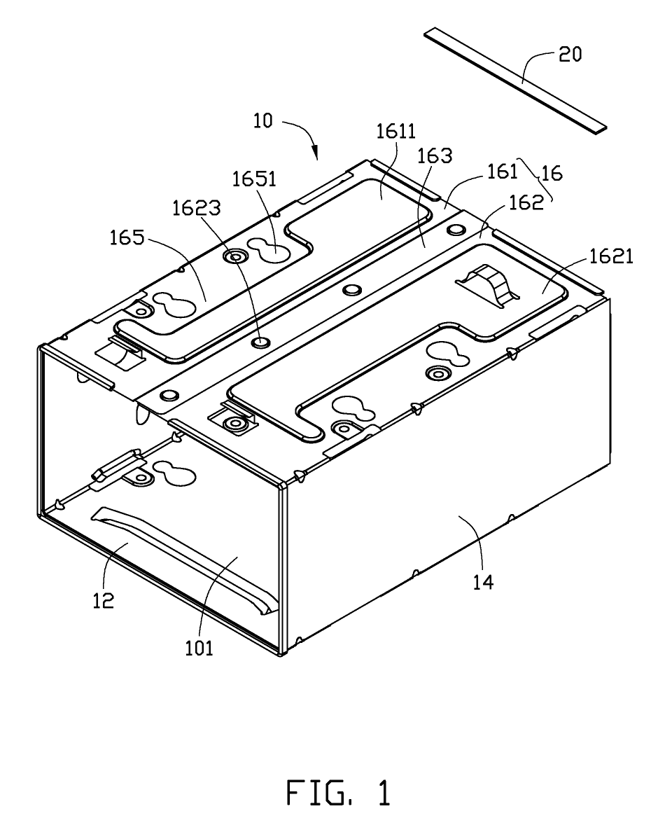

Referring to FIGS. 1 to 3, an embodiment of a bracket includes a bracket main body 10 and a reinforce rib 20. The bracket main body 10 includes a base panel 12, a pair of side panels 14 extending substantially perpendicularly from opposite sides of the base panel 12, and a top panel 16 connected between the pair of side panels 14.

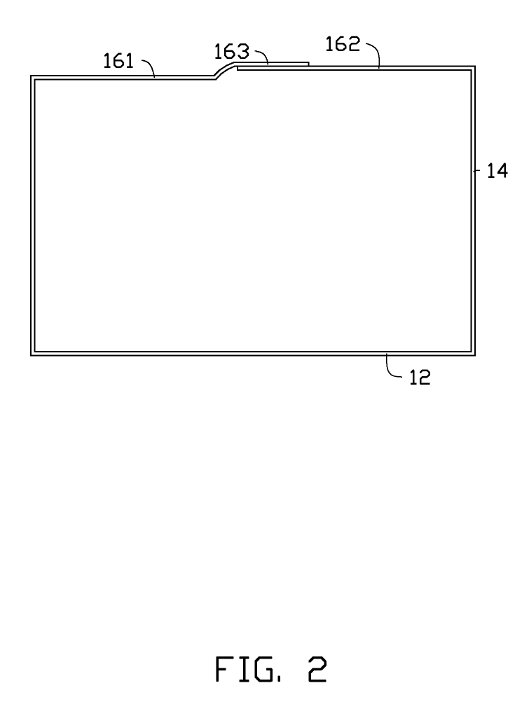

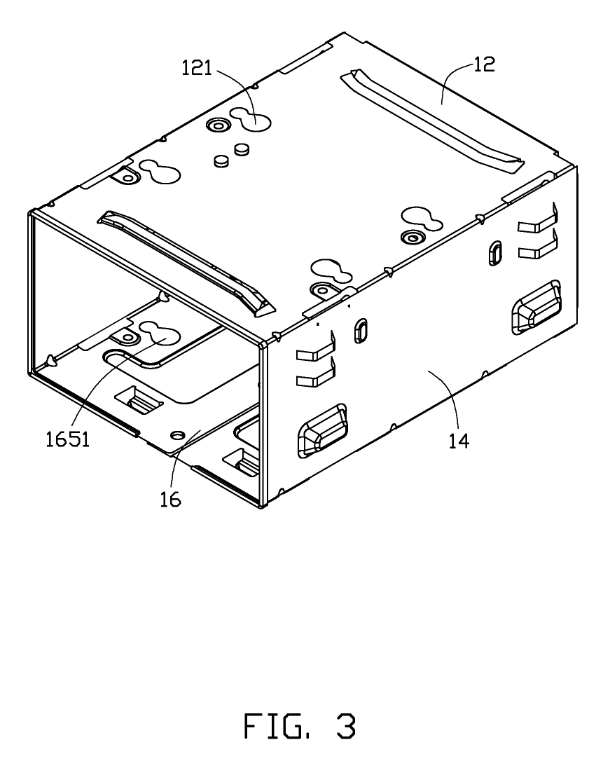

The top panel 16 includes a first plate 161 extending substantially perpendicularly from a top edge of a first side panel of the pair of side panels 14 and a second plate 162 extending substantially perpendicularly from a top edge of a second side panel of the pair of side panels 14. The first plate 161 includes a bent flange 163 abutting on the second plate 162. A plurality of securing holes (not labeled) is defined in the bent flange 163. A plurality of securing posts 1623 protrude from the second plate 162 and engages with the plurality of securing holes to secure the second plate 162 to the first plate 161. In one embodiment, the bracket main body 10 is integrally formed by bending a piece of metal plate (see FIG. 2). A first protruding portion 1611 protrudes upwardly from the first plate 161. A second protruding portion 1621 protrudes upwardly from the second plate 162. A protruding height of the first protruding portion 1611 is substantially equal to that of the second protruding portion 1621. A shape of the first protruding portion 1611 is substantially similar to that of the second protruding portion 1621. The plurality of securing posts 1623 are located between the first protruding portion 1611 and the second protruding portion 1621 and lies on a line that is substantially parallel to the pair of side panels 14. A U-shaped gap portion 165 is defined in each of the first protruding portion 1611 and the second protruding portion 1621. A pair of first calabash-shaped holes 121 is defined in the base panel 12 and located adjacent to each of the pair of side panels 14 (see FIG. 3). A pair of second calabash-shaped holes 1651 is defined on the U-shaped gap portion 165 and aligned with the pair of first calabash-shaped holes 121.

Referring to FIG. 3, in assembly, the plurality of securing posts 1623 engage with the plurality of securing holes. The first plate 161 and the second plate 162 partially overlap and fix to each other. A first end of the reinforce rib 20 can be secured to the first protruding portion 1611 by welding or other suitable means. A second end of the reinforce rib 20 can be secured to the second protruding portion 1621 by welding or other suitable means. The reinforce rib 20 is a long and narrow sheet-metal plate. A long edge of the reinforce rib 20 is substantially perpendicular to the pair of side panels 14. A short edge of the reinforce rib 20 is substantially parallel to the pair of side panels 14.

In one embodiment, the bracket main body 10 includes an entrance 101 located at a front side of the bracket main body 10. Hard disk drives (not shown) can slide into the bracket main body 10 via the entrance 101. The reinforce rib 20 is adjacent to a rear side of the bracket main body 10. A rear portion of each of the hard disk drives generates greater vibration than any other portion of each of the hard disk drives in use. The reinforce rib 20 can improve the shock-resisting ability of the bracket main body 10 and decrease the vibration of the bracket main body 10.

While the present disclosure has been illustrated by the description in this embodiment, and while the embodiment has been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A bracket comprising:
a bracket main body comprising a base panel, a pair of side panels extending from opposite sides of the base panel, and a top panel connected between the pair of side panels and opposite to the base panel; the top panel comprising a first plate extending substantially perpendicularly from an upper edge of a first side panel of the pair of side panels. and a second plate extending substantially perpendicularly from an upper edge of a second side panel of the pair of side panels; wherein the first plate and the second plate partially overlap with each other and fix to each other; and
a reinforce rib comprising a first end secured to the first plate and a second end secured to the second plate.

2. The bracket of claim 1, wherein the first plate comprises a first protruding portion, the second plate comprises a second protruding portion, the first end of the reinforce rib is secured to the first protruding portion, and the second end of the reinforce rib is secured to the second protruding portion.

3. The bracket of claim 2, wherein the bracket main body comprises an entrance located at a front side of the bracket main body, the reinforce rib is located adjacent to a rear side of the bracket main body.

4. The bracket of claim 3, wherein the reinforce rib is a long and narrow sheet-metal plate.

5. The bracket of claim 4, wherein a long edge of the reinforce rib is substantially perpendicular to the pair of side panels.

6. The bracket of claim 2, wherein the first plate comprises a bent flange abutting on the second plate, a plurality of securing holes are defined in the bent flange, the second plate comprises a plurality of securing posts engaging with the plurality of securing holes.

7. The bracket of claim 6, wherein the plurality of securing posts are located between the first protruding portion and the second protruding portion; and the plurality of securing posts are aligned on a line substantially parallel to the pair of side panels.

8. The bracket of claim 2, wherein a U-shaped gap portion is defined in each of the first protruding portion and the second protruding portion.

9. The bracket of claim 8, wherein a pair of calabash-shaped holes are defined in the U-shaped gap portion.

10. The bracket of claim 1, wherein the bracket main body is integrally formed by bending a piece of metal plate.

11. A bracket comprising:
a bracket main body comprising a base panel, a pair of side panels extending from opposite sides of the base panel, a first plate extending substantially perpendicularly from an upper edge of a first side panel of the pair of side panels, and a second plate extending substantially perpendicularly from an upper edge of a second side panel of the pair of side panels; wherein the first plate and the second plate are partially overlapped with each other and fixed to each other; and
a reinforce rib comprising a first end secured to the first plate and a second end secured to the second plate, a long edge of the reinforce rib being substantially perpendicular to the pair of side panels, and a short edge of the reinforce rib being substantially parallel to the pair of side panels.

12. The bracket of claim 11, wherein the first plate comprises a first protruding portion, the second plate comprises a second protruding portion, the first end of the reinforce rib is secured to the first protruding portion, and the second end of the reinforce rib is secured to the second protruding portion.

13. The bracket of claim 12, wherein the bracket main body comprises an entrance located at a front side of the bracket main body, the reinforce rib is located adjacent to a rear side of the bracket main body.

14. The bracket of claim 13, wherein the reinforce rib is a long and narrow sheet-metal plate.

15. The bracket of claim 12, wherein the first plate comprises a bent flange abutting on the second plate, a plurality of securing holes are defined in the bent flange, the second plate comprises a plurality of securing posts engaging with the plurality of securing holes.

16. The bracket of claim 15, wherein the plurality of securing posts are located between the first protruding portion and the second protruding portion; and the plurality of securing posts are aligned on a line substantially parallel to the pair of side panels.

17. The bracket of claim 12, wherein a U-shaped gap portion is defined in each of the first protruding portion and the second protruding portion.

18. The bracket of claim 17, wherein a pair of first calabash-shaped holes are defined in the base panel beside each of the pair of side panels, a pair of second calabash-shaped holes are defined in the U-shaped gap portion, each of the pair of second calabash-shaped holes is aligned with each of the pair of first calabash-shaped holes.
